(19) United States
(12) Patent Application Publication
(10) Pub. No.: US 2026/0031177 A1
(43) Pub. Date: Jan. 29, 2026

(54) PARITY SCHEME FOR READ DISTRESS PROTECTION IN A MEMORY SYSTEM

(71) Applicant: Micron Technology, Inc., Boise, ID (US)

(72) Inventors: Andrea Vigilante, Milano (IT); Sean L. Manion, Boise, ID (US); Paolo Amato, Treviglio (IT); Peter Feeley, Boise, ID (US); Xiangang Luo, Fremont, CA (US); Giuseppe Rizzari, Ragusa (IT)

(21) Appl. No.: 19/273,971

(22) Filed: Jul. 18, 2025

Related U.S. Application Data
(60) Provisional application No. 63/674,918, filed on Jul. 24, 2024.

(51) Int. Cl. G11C 29/52; G11C 16/04; G11C 16/10; G11C 16/26

(52) U.S. Cl. CPC G11C 29/52; G11C 16/0483; G11C 16/102; G11C 16/26

(57) ABSTRACT

Methods, systems, and devices for a parity scheme for read distress protection in a memory system are described. The parity scheme described herein may protect data against read distress errors. A set of consecutive word lines in a memory system may include one or more word line groups and one or more sub-block groups. The memory system may store, in a word line group of the set of consecutive word lines, parity information for the set of consecutive word lines. Each parity page may be a combination of one page of data per sub-block group and per word line group of the set of consecutive word lines. For example, each sub-block group and each word line group may contain N pages, where each of the N pages may correspond to a unique parity page to provide for recovery from errors caused by both read and program distresses.

### CROSS REFERENCE

The present Application for Patent claims priority to U.S. Patent Application No. 63/674,918 by Vigilante et al., entitled “PARITY SCHEME FOR READ DISTRESS PROTECTION IN A MEMORY SYSTEM,” filed Jul. 24, 2024, which is assigned to the assignee hereof, and which is expressly incorporated by reference in its entirety herein.

### TECHNICAL FIELD

The following relates to one or more systems for memory, including parity scheme for read distress protection in a memory system.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 shows an example of a system that supports a parity scheme for read distress protection in a memory system in accordance with examples as disclosed herein.

FIG. 2 shows an example of a memory architecture that supports the parity scheme for read distress protection in a memory system in accordance with examples as disclosed herein.

FIG. 3 shows an example of a memory architecture that supports the parity scheme for read distress protection in a memory system in accordance with examples as disclosed herein.

FIG. 4 shows an example of a parity configuration that supports the parity scheme for read distress protection in a memory system in accordance with examples as disclosed herein.

FIG. 5 shows a block diagram of a memory system that supports the parity scheme for read distress protection in a memory system in accordance with examples as disclosed herein.

FIG. 6 shows a flowchart illustrating a method or methods that support the parity scheme for read distress protection in a memory system in accordance with examples as disclosed herein.

### DETAILED DESCRIPTION

A memory system may include one or more dies of pages (e.g., pages of memory, data pages), each die including one or more planes (e.g., one or more planes of pages). In some examples, a set of consecutive word lines within the one or more planes may include pages across each plane of each die of the memory system. The set of consecutive word lines may include one or more sub-blocks (e.g., sub-blocks of pages), where a group of adjacent sub-blocks (e.g., a sub-block group) may be associated with one select gate source (SGS) (e.g., segmented SGSs, a source selector) and one or more select gate drains (SGDs) (e.g., drain selectors). In some cases, data stored in the one or more pages may be programmed per word line and may be read per sub-block (e.g., or by page). However, writing and reading data to and from the one or more pages may cause errors in the one or more pages, in some cases. For example, program disturb errors may affect one or more pages in word lines adjacent to a written word line due to parasitic voltages between adjacent word lines during programming. Additionally, or alternatively, one or more sub-blocks coupled with an SGS (e.g., columns that are not selected by a corresponding SGD) may experience read distress errors due to being coupled with a source node voltage in response to another sub-block coupled with the SGS being read.

Some memory systems may generate parity information to correct errors within one or more pages. For example, the memory system may generate the parity information on a per page basis for all the word lines in the one or more dies by combining (e.g., via an exclusive OR (XOR) or other logical operation) respective pages of each word line, and may store the parity information in a word line at the end of the one or more dies. That is, the memory system may combine each page in a sub-block (e.g., in a virtual sub-block, in a column, corresponding to one SGD) to generate a page of parity information (e.g., a parity page). If an error is identified, the memory system may recover data for an errored page of a word line by combining the stored parity information with corresponding pages from each other word line and generating the corrected data for the errored page. However, if multiple pages of a sub-block incur errors simultaneously (e.g., such as with a read distress error), the memory system may not have access to enough accurate (e.g., un-errored) data from the other word lines to combine with the stored parity information and recover the data for the multiple pages. Thus, a parity scheme capable of protecting data against read distress errors (e.g., as well as program disturb errors) may be beneficial.

According to techniques described herein, a memory system may implement an error recovery or error correction scheme (e.g., a redundant array of independent not-AND (NAND) (RAIN) scheme) to protect data against program disturb errors and read distress errors. The error recovery scheme may generate and store parity information in such a way that multiple errors within a same sub-block may be corrected at the same time. For example, as described herein, the multiple word lines across the one or more planes of the one or more dies in the memory system may include one or more sets of consecutive word lines. Each set of consecutive word lines may include one or more word line groups (e.g., subsets of two or more adjacent word lines) and one or more sub-block groups (e.g., subsets of one or more adjacent sub-blocks or virtual sub-blocks). In some cases, the parity scheme described herein may include storing parity pages for each set of consecutive word lines in a respective word line group of each set of consecutive word lines (e.g., instead of at an end of a die). The memory system may calculate each parity page for a set of consecutive word lines by combining (e.g., via an XOR) data stored in a respective set of pages associated with the given parity page. Each set of pages in the set of consecutive word lines may include one page of data per sub-block group and one page of data per word line group of the set of consecutive word lines. For example, each sub-block group and each word line group may contain N unique pages, where each of the N pages may correspond to a unique parity page from among N parity pages. A given set of pages associated with a single parity page, may include the one page from each sub-block group (e.g., and each word line group) and each of the one pages may be in a different location within each sub-block group (e.g., or word line group). The described parity scheme may thereby provide for correction of errors affecting a same word line (e.g., a same row, due to program disturb errors) of the memory system and correction of errors affecting a same sub-block (e.g., a same column, due to read distress errors). By calculating the parity pages in such a fashion, the memory system may recover all or most pages of a sub-block group (e.g., or a word line group) at the same time (e.g., in the case of read distress errors or program disturb errors) in response to each parity element being calculated from a single page of each sub-block group and a single page from each word line group.

In addition to applicability in memory systems as described herein, techniques for a parity scheme for read distress protection in a memory system may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by providing parity protection against errors resulting from read distress, which may reduce errors in the data and improve performance, among other benefits.

In addition to applicability in memory systems described herein, techniques for a parity scheme for read distress protection in a memory system may be generally implemented to improve security and/or authentication features of various electronic devices and systems. As the use of electronic devices for handling private, user, or other sensitive information has become even more widespread, electronic devices and systems have become the target of increasingly frequent and sophisticated attacks. Further, unauthorized access or modification of data in security-critical devices such as vehicles, healthcare devices, and others may be especially concerning. Implementing the techniques described herein may improve the security of electronic devices and systems by providing parity protection against errors resulting from read distress, which may reduce errors and keep the data in the memory system more secure, among other benefits.

Features of the disclosure are illustrated and described in the context of systems, devices, and circuits. Features of the disclosure are further illustrated and described in the context of memory architectures, parity configurations, block diagrams, and flowcharts.

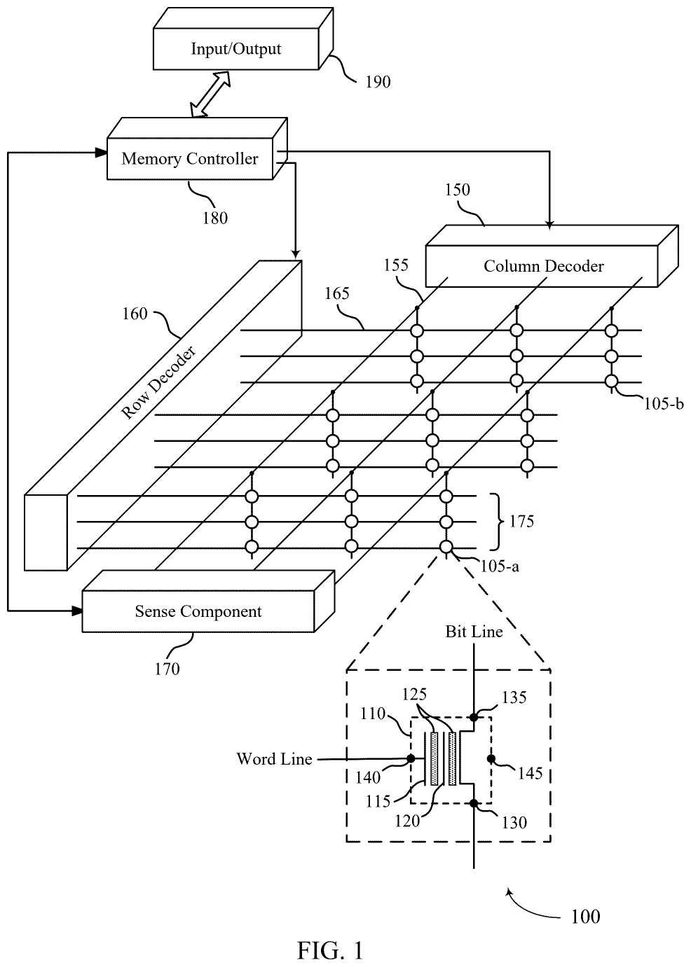

FIG. 1 shows an example of a memory device 100 that supports a parity scheme for read distress protection in a memory system in accordance with examples as disclosed herein. FIG. 1 is an illustrative representation of various components and features of the memory device 100. As such, the components and features of the memory device 100 are shown to illustrate functional interrelationships, and not necessarily physical positions within the memory device 100. Further, although some elements included in FIG. 1 are labeled with a numeric indicator, some other corresponding elements are not labeled, even though they are the same or would be understood to be similar, in an effort to increase visibility and clarity of the depicted features.

The memory device 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., according to a presence or absence of a current through the memory cell 105 when a read voltage is applied to the control gate 115, according to whether the current is above or below a threshold current). For a multiple-level memory cell 105, a sense component 170 may determine a logic value stored in the memory cell 105 according to various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 according to eight different levels of current, or ranges of current, that define the eight potential logic values that could be stored by the TLC memory cell 105.

An SLC memory cell 105 may be written by applying one of two voltages (e.g., a voltage above a threshold or a voltage below a threshold) to the memory cell 105 to store, or not store, an electric charge on the charge trapping structure 120 and thereby cause the memory cell 105 to store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as access lines or select lines.

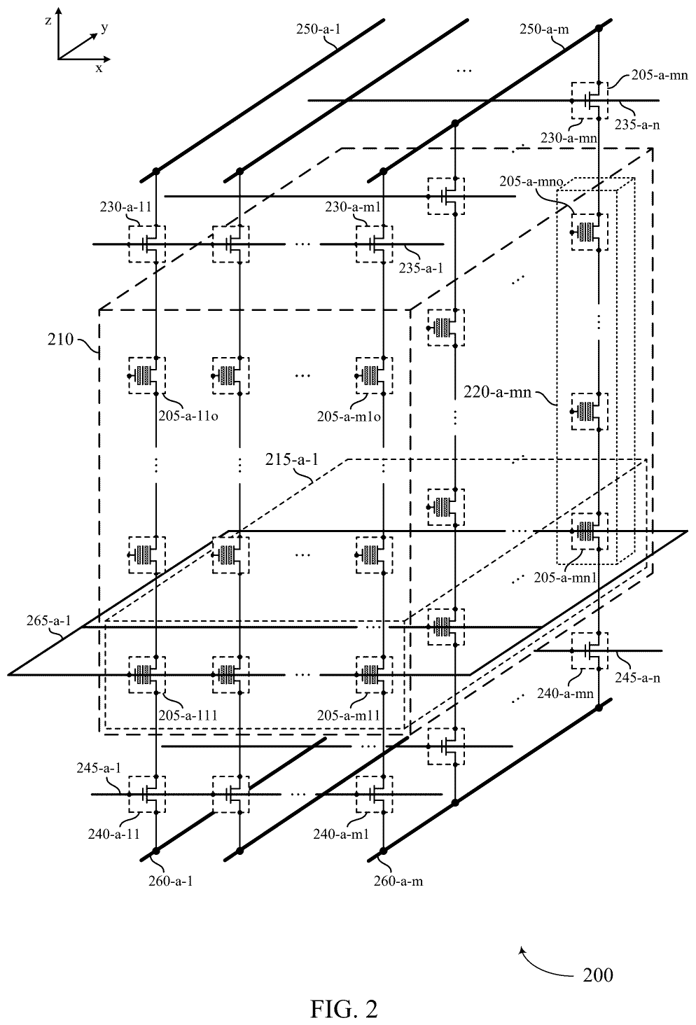

In some cases, a memory device 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, memory device 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105 (e.g., as described with reference to FIG. 2).

Accessing memory cells 105 may be controlled through a row decoder 160 and a column decoder 150. For example, the row decoder 160 may receive a row address from the memory controller 180 and activate an appropriate word line 165 according to the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 according to a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of memory device 100.

The memory device 100 may include any quantity of non-transitory computer readable media that support a parity scheme for read distress protection in a memory system. For example, a host system, the system controller, or the memory device 100 may include or otherwise may access one or more non-transitory computer readable media storing instructions (e.g., firmware) for performing the functions ascribed herein to the host system, system controller, or memory device 100. For example, such instructions, if executed by the host system (e.g., by a host system controller), by the system controller, or by the memory device 100 (e.g., by a memory controller 180), may cause the host system, system controller, or memory device 100 to perform associated functions as described herein.

According to techniques described herein, a memory system may implement a parity scheme (e.g., a RAIN scheme) to protect data against or otherwise correct program disturb errors and read distress errors. In some cases, the memory system may include a word lines 165 including pages of data across one or more planes of one or more dies, where the word lines 165 may include one or more sets of consecutive word lines, and each set of consecutive word lines may include one or more word line groups and sub-block groups. In some cases, the parity scheme may include storing parity pages for each set of consecutive word lines in a respective word line group of each set of consecutive word lines, where the memory system may calculate each parity page for a set of consecutive word lines by combining (e.g., via an XOR operation) one page of data per sub-block group and per word line group of the set of consecutive word lines. For example, each sub-block group and each word line group may contain N pages, where each of the N pages may correspond to a unique parity page of N parity pages. Additionally, the one page of each sub-block group (e.g., and each word line group) corresponding to a parity page may be in a different location of each sub-block group (e.g., or word line group), such that errors affecting a same word line 165 (e.g., a same row, due to program disturb errors) of the memory system and errors affecting a same sub-block (e.g., a same column, due to read distress errors) may both be corrected. By calculating the parity pages in such a fashion, the memory system may recover all pages of a sub-block group (e.g., or a word line group) at the same time (e.g., in the case of read distress errors or program disturb errors) in response to each parity element being calculated from a single page of each sub-block group and a single page from each word line group.

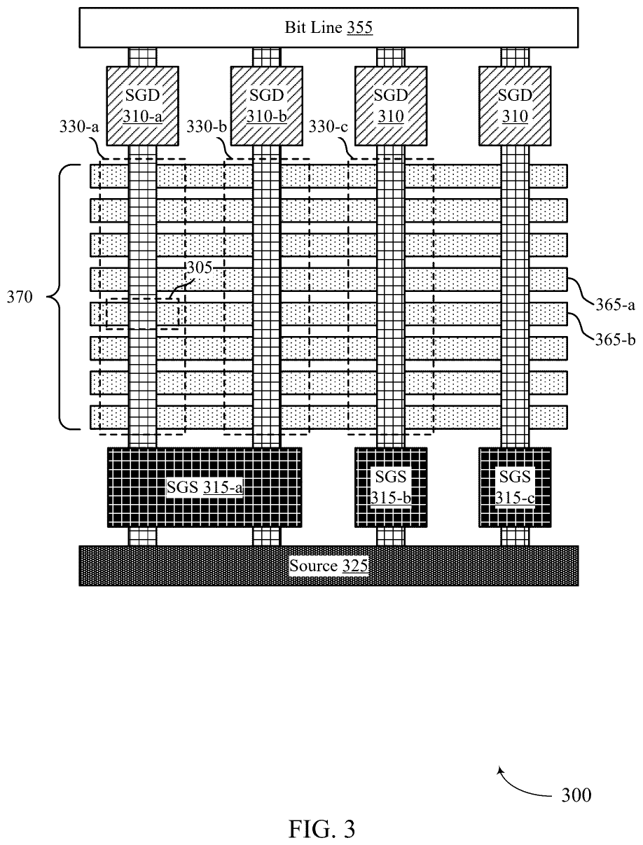

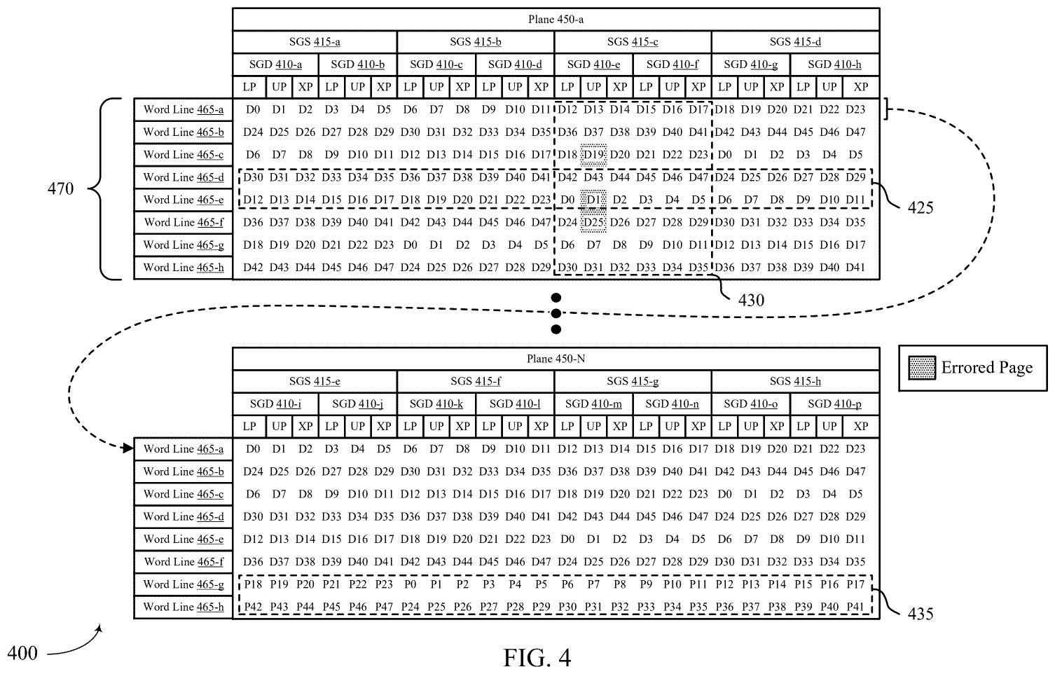

In some aspects, the memory controller 180 may implement one or more aspects of the parity scheme described herein in the memory device 100. For example, the memory controller 180 may select one or more pages to use in calculating the parity pages according to the one or more word line groups and one or more sub-block groups. Additionally, or alternatively, the memory controller 180 may perform one or more data recovery procedures (e.g., as described herein with respect to FIGS. 3 and 4) using the calculate parity information to recover data from read distress errors.

FIG. 2 shows an example of a memory architecture 200 that supports the parity scheme for read distress protection in a memory system in accordance with examples as disclosed herein. The memory architecture 200 may be an example of a portion of a memory device, such as a memory device 100. Although some elements of a set of elements (e.g., an array of elements) are included in FIG. 2, some elements may be omitted for the sake of visibility and clarity of the depicted elements. Moreover, although some elements included in FIG. 2 are labeled with reference numbers, some other corresponding elements are not labeled, though they would be understood by a person having ordinary skill in the art to be the same as or similar to the labeled elements. Aspects of the memory architecture 200 may be described with reference to an x-direction, a y-direction, and a z-direction of the illustrated coordinate system.

The memory architecture 200 includes a three-dimensional array of memory cells 205, which may be examples of memory cells 105 described with reference to FIG. 1 (e.g., transistors 110, NAND memory cells). In some examples, the memory cells 205 may be connected in a 3D NAND configuration. For example, the memory cells 205 may be included in a block 210, which may be arranged as a 3D array of m memory cells along the x-direction, n memory cells along the y-direction, and o memory cells along the z-direction. Each memory cell 205 may be located (e.g., addressed) in accordance with an index i along the x-direction, an index j along the y-direction, and an index k along the z-direction (e.g., for locating a memory cell 205-a-ijk). A memory device 100 may include any quantity of one or more blocks 210 in accordance with examples as disclosed herein, and different blocks 210 may be adjacent along the x-direction, along the y-direction, or along the z-direction, or any combination thereof.

In the example of memory architecture 200, the block 210 may be divided into a set of pages 215 (e.g., a quantity of o pages 215) along the z-direction, including a page 215-a-1 associated with memory cells 205-a-111 through 205-a-mn1. In some examples, each page 215 may be associated with the same word line 265, (e.g., a word line 165 described with reference to FIG. 1), which may be coupled with a control gate 115 of each of the memory cells 205 of the page 215. For example, page 215-a-1 may be associated with a word line 265-a-1, and other pages 215-a-i may be associated with a different respective word line 265-a-i (not shown). In some examples, a word line 265 in accordance with the memory architecture 200 may be implemented as planar conductor (e.g., in an xy-plane) that is coupled with each of the memory cells 205 of the page 215.

In the example of memory architecture 200, the block 210 also may be divided into a set of strings 220 (e.g., a quantity of (m×n) strings 220) in an xy-plane, including a string 220-a-mn associated with memory cells 205-a-mn1 through 205-a-mno. In some examples, each string 220 may include a set of memory cells 205 connected in series (e.g., along the z-direction, in which a drain of one memory cell 205 in the string 220 may be coupled with a source of another memory cell 205 in the string 220). In some examples, memory cells 205 of a string 220 may be implemented along a common channel, such as a pillar channel (e.g., a columnar channel, a pillar of doped semiconductor) along the z-direction. Each memory cell 205 in a string 220 may be associated with a different word line 265, such that a quantity of word lines 265 in the memory architecture 200 may be equal to the quantity of memory cells 205 in a string 220. Accordingly, a string 220 may include memory cells 205 from multiple pages 215, and a page 215 may include memory cells 205 from multiple strings 220.

In some examples, memory cells 205 may be programmed (e.g., set to a logic 0 value) and read from in accordance with a granularity, such as at the granularity of a page 215 or portion thereof, but may not be erasable (e.g., reset to a logic 1 value) in accordance with the granularity, such as the granularity of a page 215 or portion thereof. For example, NAND memory may instead be erasable in accordance with a different (e.g., higher) level of granularity, such as at the level of granularity the block 210. In some cases, a memory cell 205 may be erased before it may be re-programmed. Different memory devices may have different read, write, or erase characteristics.

In some examples, each string 220 of a block 210 may be coupled with a respective transistor 230 (e.g., a string select transistor, a drain select transistor) at one end of the string 220 (e.g., along the z-direction) and a respective transistor 240 (e.g., a source select transistor, a ground select transistor) at the other end of the string 220. In some examples, a drain of each transistor 230 may be coupled with a bit line 250 of a set of bit lines 250 associated with the block 210, where the bit lines 250 may be examples of bit lines 155 described with reference to FIG. 1. A gate of each transistor 230 may be coupled with a select line 235 (e.g., a string select line, a drain select line). Thus, a transistor 230 may be used to couple a string 220 with a bit line 250 by applying a voltage to the select line 235, and thus to the gate of the transistor 230. Although illustrated as separate lines along the x-direction, in some examples, select lines 235 may be common to all the transistors 230 associated with the block 210 (e.g., a commonly biased string select node). For example, like the word lines 265 of the block 210, select lines 235 associated with the block 210 may, in some examples, be implemented as a planar conductor (e.g., in an xy-plane) that is coupled with each of the transistors 230 associated with the block 210.

In some examples, a source of each transistor 240 associated with the block 210 may be coupled with a source line 260 of a set of source lines 260 associated with the block 210. In some examples, the set of source lines 260 may be associated with a common source node (e.g., a ground node) corresponding to the block 210. A gate of each transistor 240 may be coupled with a select line 245 (e.g., a source select line, a ground select line). Thus, a transistor 240 may be used to couple a string 220 with a source line 260 by applying a voltage to the select line 245, and thus to the gate of the transistor 240. Although illustrated as separate lines along the x-direction, in some examples, select lines 245 also may be common to all the transistors 240 associated with the block 210 (e.g., a commonly biased ground select node). For example, like the word lines 265 of the block 210, select lines 245 associated with the block 210 may, in some examples, be implemented as a planar conductor (e.g., in an xy-plane) that is coupled with each of the transistors 240 associated with the block 210.

To operate the memory architecture 200 (e.g., to perform a program operation, a read operation, or an erase operation on one or more memory cells 205 of the block 210), various voltages may be applied to one or more select lines 235 (e.g., to the gate of the transistors 230), to one or more bit lines 250 (e.g., to the drain of one or more transistors 230), to one or more word lines 265, to one or more select lines 245 (e.g., to the gate of the transistors 240), to one or more source lines 260 (e.g., to the source of the transistors 240), or to a bulk for the memory cells 205 (not shown) of the block 210. In some cases, each memory cell 205 of a block 210 may have a common bulk, the voltage of which may be controlled independently of bulks for other blocks 210.

In some cases, as part of a read operation for a memory cell 205, a positive voltage may be applied to the corresponding bit line 250 while the corresponding source line 260 may be grounded or otherwise biased at a voltage lower than the voltage applied to the bit line 250. In some examples, voltages may be concurrently applied to the select line 235 and the select line 245 that are above the threshold voltages of the transistor 230 and the transistor 240, respectively, for the memory cell 205, thereby activating the transistor 230 and transistor 240 such that a channel associated with the string 220 that includes the memory cell 205 (e.g., a pillar channel) may be electrically connected with (e.g., electrically connected between) the corresponding bit line 250 and source line 260. A channel may be an electrical path through the memory cells 205 in the string 220 (e.g., through the sources and drains of the transistors in the memory cells 205 of the string 220) that may conduct current under some operating conditions.

In some examples, multiple word lines 265 (e.g., in some cases all word lines 265) of the block 210—except a word line 265 associated with a page 215 of the memory cell 205 to be read—may concurrently be set to a voltage (e.g., VREAD) that is higher than the threshold voltage (VT) of the memory cells 205. VREAD may cause all memory cells 205 in the unselected pages 215 be activated so that each unselected memory cell 205 in the string 220 may maintain high conductivity within the channel. In some examples, the word line 265 associated with the memory cell 205 to be read may be set to a voltage, VTarget. Where the memory cells 205 are operated as SLC memory cells, VTarget may be a voltage that is between (i) VT of a memory cell 205 in an erased state and (ii) VT of a memory cell 205 in a programmed state.

When the memory cell 205 to be read exhibits an erased VT (e.g., VTarget>VT of the memory cell 205), the memory cell 205 may turn “ON” in response to the application of VTarget to the word line 265 of the selected page 215, which may allow a current to flow in the channel of the string 220, and thus from the bit line 250 to the source line 260. When the memory cell 205 to be read exhibits a programmed VT (e.g., VTarget<VT of the selected memory cell), the memory cell 205 may remain “OFF” despite the application of VTarget to the word line 265 of the selected page 215, and thus may prevent a current from flowing in the channel of the string 220, and thus from the bit line 250 to the source line 260.

A signal on the bit line 250 for the memory cell 205 (e.g., an amount of current below or above a threshold) may be sensed (e.g., by a sense component 170 as described with reference to FIG. 1), and may indicate whether the memory cell 205 became conductive or remained non-conductive in response to the application of VTarget to the word line 265 of the selected page 215. The sensed signal thus may be indicative of whether the memory cell 205 was in an erased state (e.g., storing a logic 1) or a programmed state (e.g., storing a logic 0). Though aspects of the example read operation above have been explained in the context of an SLC memory cell 205 for clarity, such techniques may be extended or altered and applied in the context of a multiple-level memory cell 205 (e.g., through the use of multiple values of VTarget corresponding to the different amounts of charge that may be stored in one multiple-level memory cell 205).

In some cases, as part of a program operation for a memory cell 205, charge may be added to a portion of the memory cell 205 such that current flow through the memory cell 205, and thus the corresponding string 220, may be inhibited when the memory cell 205 is later read. For example, charge may be injected into a charge trapping structure 120 as shown in memory cell 105-a of FIG. 1. In some cases, respective voltages may be applied to the word line 265 of the page 215 and the bulk of the memory cell 205 to be programmed such that a control gate 115 of the memory cell 205 is at a higher voltage than the bulk of the memory cell 205 (e.g., a positive voltage may be applied to the word line). Concurrently, voltages may be applied to the select line 235 and the select line 245 that are above the threshold voltages of the transistor 230 and the transistor 240, respectively, thereby activating the transistor 230 and the transistor 240, and the bit line 250 for the memory cell 205 to be programmed may be set to a relatively high voltage. This may cause an electric field such that electrons are pulled from the source of the memory cell 205 towards the drain. The electric field may also cause some of these electrons to be pulled through dielectric material 125 and thereby injected into the charge trapping structure 120 of the memory cell 205, through a process which may in some cases be referred to as tunnel injection.

In some cases, a single program operation may program some or all memory cells 205 in a page 215, as the memory cells 205 of the page 215 may all share a common word line 265 and a common bulk. For a memory cell 205 of the page 215 for which it is not desired to write a logic 0 (e.g., not desired to program the memory cell 205), the corresponding bit line 250 may be set to a relatively low voltage (e.g., ground), which may inhibit the injection of electrons into a charge trapping structure 120. Though aspects of the example program operation above have been explained in the context of an SLC memory cell 205 for clarity, such techniques may be extended and applied to the context of a multiple-level memory cell 205 (e.g., through the use of multiple programming voltages applied to the word line 265, or multiple passes or pulses of a programming voltage applied to the word line 265, corresponding to the different amounts of charge that may be stored in one multiple-level memory cell 205).

In some cases, as part of an erase operation for a memory cell 205, charge may be removed from a portion of the memory cell 205 such that current flow through the memory cell 205, and thus the corresponding string 220, may be uninhibited (e.g., allowed, at least to a greater extent) when the memory cell 205 is later read. For example, charge may be removed from a charge trapping structure 120 as shown in memory cell 105-a of FIG. 1. In some cases, respective voltages may be applied to the word line 265 of the page 215 and the bulk of the memory cell 205 to be erased such that a control gate 115 of the memory cell 205 is at a lower voltage than the bulk of the memory cell 205 (e.g., a positive voltage may be applied to the bulk), which may cause an electric field that pulls electrons out of the charge trapping structure 120 and into the bulk of the memory cell 205. In some cases, a single program operation may erase all memory cells 205 in a block 210, as the memory cells 205 of the block 210 may all share a common bulk.

According to techniques described herein, a memory system may implement a parity scheme (e.g., a RAIN scheme) to protect data against program disturb errors and read distress errors. In some cases, the memory system may include word lines 265 including pages of data across one or more planes of one or more dies, where the word lines 265 may include one or more sets of consecutive word lines, and each set of consecutive word lines may include one or more word line groups and sub-block groups. In some cases, the parity scheme may include storing parity pages for each set of consecutive word lines in a respective word line group of each set of consecutive word lines, where the memory system may calculate each parity page for a set of consecutive word lines by combining (e.g., via an XOR operation) one page 215 of data per sub-block group and per word line group of the set of consecutive word lines. For example, each sub-block group and each word line group may contain N pages 215, where each of the N pages 215 may correspond to a unique parity page of N parity pages. Additionally, the one page 215 of each sub-block group (e.g., and each word line group) corresponding to a parity page may be in a different location of each sub-block group (e.g., or word line group), such that errors affecting a same word line 265 (e.g., a same row, due to program disturb errors) of the memory system and errors affecting a same sub-block (e.g., a same column, due to read distress errors) may both be corrected. By calculating the parity pages in such a fashion, the memory system may recover all pages 215 of a sub-block group (e.g., or a word line group) at the same time (e.g., in the case of read distress errors or program disturb errors) in response to each parity element being calculated from a single page 215 of each sub-block group and a single page 215 from each word line group.

FIG. 3 shows an example of a memory architecture 300 that supports the parity scheme for read distress protection in a memory system in accordance with examples as disclosed herein. In some cases, aspects of the memory architecture 300 may implement or be implemented by aspects of FIGS. 1 and 2. For example, the memory architecture 300 may include memory cells 305 (e.g., such as the memory cells 105, memory cells 205, or both), a bit line 355 (e.g., such as the bit lines 155, the bit lines 250, or both), and word lines 365 (e.g., such as the word lines 165, the word lines 265, or both). In some aspects, the memory architecture 300 may show a plurality of memory cells of a memory system (e.g., such as the memory device 100) that may be accessed via SGSs 315, where the SGSs 315 may be segmented to reduce read distress errors in the plurality of memory cells.

Although the memory architecture 300 may include memory cells 305, the data stored in one or more of the memory cells 305 of the memory architecture 300 may be analogous to data stored in a page of memory (e.g., such as the pages of data described herein with respect to FIG. 4). For example, as described with reference to FIG. 2, a page (e.g., a page 215) may include one or more memory cells 305. The techniques described herein may apply to a set of memory cells 305, a set of pages, or any other unit of memory storage. The memory architecture 300 may represent a portion of a memory system or of a memory device, and the quantities of SGDs 310, SGSs 315, memory cells 305, word lines 365, and any other feature of the memory architecture 300, are in no way limiting to the techniques described herein.

In some cases, the memory cells 305 of a word line 365 may be programmed together (e.g., simultaneously, in one programming cycle). While programming the memory cells 305 of a word line 365-a, a parasitic coupling between the word line 365-a and at least one adjacent word line 365-b (e.g., due to malfunctions in manufacturing, capacitive coupling, or other coupling circumstances) may cause an error in the data stored by one or more memory cells 305 of the adjacent word line 365-b (e.g., change the voltage in the one or more memory cells 305 to represent a different logical value than intended). Such errors in adjacent word lines from programming a word line may be referred to as a programming disturb errors, and may affect one or more memory cells 305 within a same word line 365.

Additionally, or alternatively, reading a memory cell 305 may include selectively activating one or more SGDs 310 and one or more SGSs 315 associated with the memory cell 305. For example, to access data in the memory cell 305 illustrated in FIG. 3, the memory system may activate SGD 310-a to couple a sub-block 330-a of memory cells 305 to the bit line 355. The memory system may also activate the SGS 315-a, which may couple the sub-block 330-a and a sub-block 330-b (e.g., an adjacent sub-block to sub-block 330-a) to a source 325 (e.g., a ground node). Such selective activation of the SGD 310-a and the SGS 315-a may allow reading of data stored in the memory cell 305 in the sub-block 330-a. However, coupling the sub-block 330-b with the source 325 may set at least a portion of the sub-block 330-b to a voltage level of the source 325 (e.g., ground voltage, zero volts) due to the sub-blocks 330-a and 330-b sharing the same SGS 315-a, which may cause errors in data stored in the sub-block 330-b. If an SGD 310-b coupled with the sub-block 330-b is not activated, the memory cells 305 of the sub-block 330-b may not be read, however, a voltage level stored in the memory cells 305 of the sub-block 330-b may be affected (e.g., altered, lowered) due to the portion of the sub-block 330-b being set to the voltage level of the source 325. Accordingly, a voltage level in the one or more memory cells 305 of the sub-block 330-b may change to represent a different logical value than intended in response to reading the memory cells 305 from the sub-block 330-a, which may be referred to as a read distress error. As the entire sub-block 330-b or most of the sub-block 330-b may experience the same read distress, read distress errors may affect multiple memory cells 305 of the sub-block 330-b simultaneously.

In some examples, segmented SGSs may reduce a risk of read distress errors in a memory system. For example, the SGSs 315-a, 315-b, and 315-c may be segmented from each other, which may reduce the risk of read distress errors in the memory cells 305 of the memory architecture 300. In some examples, the SGS 315-b may be coupled with a sub-block 330-c, and thus activating the SGS 315-b may not couple other sub-blocks 330 to the source 325 and cause read distress errors. Additionally, or alternatively, the SGS 315-a may be coupled with the sub-blocks 330-a and 330-b, which may reduce or otherwise mitigate a risk of read distress errors in other sub-blocks 330 in response to activating the reading from the sub-block 330-a or 330-b. As shown in the memory architecture 300, a memory system may include various levels of SGS segmentation, where any quantity of one or more sub-blocks 330 may be coupled with an SGS 315. In some examples, increasing a quantity of SGSs 315 (e.g., increasing a level of SGS segmentation) in a memory system may correspond to a decreased quantity of read distress errors in the memory system, an increased manufacturing cost of the memory system, or both.

In some cases, a memory system may calculate and store parity information for recovery of data (e.g., to correct errors in data) stored in memory cells 305. In some examples, a memory system may calculate parity information for each sub-block 330 of data. For example, the memory system may combine (e.g., XOR) data from each memory cell 305 (e.g., or page of memory cells 305) in a sub-block 330, and may store the parity information in the memory system. In other words, the memory system may combine each memory cell 305 of each word line 365 with each corresponding memory cell 305 of each other word line 365 of the memory system to create parity information for the data stored in the memory cells 305.

In the event of an error, the memory system may use the parity information to correct the error. For example, if data stored in the memory cell 305 (e.g., or a page of memory cells 305) incurs an error, the memory system may combine the stored parity information for the data of the sub-block 330-a with the data (e.g., un-errored data) from each other (e.g., un-errored) memory cell 305 of the sub-block 330-a to recover (e.g., retrieve) the un-errored data of the memory cell 305. In some examples, multiple memory cells 305 from a same word line 365 may include errors and may be corrected using the stored parity information. However, if multiple memory cells 305 of a same sub-block 330 include errors simultaneously (e.g., such as in the case of read distress errors), the memory system may not be able to use the stored parity information to correct the errors due to not having access to enough un-errored data of the sub-block 330 to recover the un-errored data of one memory cell 305 from the stored parity information.

According to techniques described herein, a memory system may implement a parity scheme (e.g., a RAIN scheme) to protect data against program disturb errors and read distress errors. For example, a memory system may include one or more sets of consecutive word lines 370, where each word line of each set of consecutive word lines 370 may include a plurality of pages spread across one or more dies and one or more planes (not shown in FIG. 3). Additionally, each set of consecutive word lines 370 may include one or more word line groups each including one or more adjacent word lines 365 (e.g., such as word lines 365-a and 365-b), and each set of consecutive word lines 370 may include one or more sub-block groups each including one or more adjacent sub-blocks 330 that are coupled with a same SGS 315 (e.g., such as sub-blocks 330-a and 330-b). The segmentation of SGSs 315 (e.g., instead of a single SGS 315 coupled with all sub-blocks 330), may provide for support of smaller sub-block groups, which may facilitate the parity scheme described herein. According to the parity scheme, the memory system may calculate a word line group of parity pages (e.g., parity information) for each set of consecutive word lines 370, where the memory system may calculate each parity page by combining (e.g., XORing) one page of data (e.g., or the data of one memory cell 305, where the data of a memory cell 305 and a page of memory may be analogous) per word line group and per sub-block group (e.g., where the word line groups and sub-block groups may overlap, such that each page of data is from a unique pair of a word line group and sub-block group).

For example, each sub-block group and each word line group within a set of consecutive word lines 370 may contain some quantity of pages (e.g., N pages). Each page of the N pages may correspond to (e.g., be included in, be used for calculation of) a unique parity page (e.g., such that the set of consecutive word lines 370 may include or otherwise be associated with N parity pages). In some cases, to generate a parity page, the memory system may avoid (e.g., or may not) combining (e.g., select for combination) more than one page from any single sub-block group or more than one page from any single word line group into a single parity page. That is, each parity page may correspond to one (e.g., a single) page of data per word line group and per sub-block group, which may allow the memory system to correct program disturb errors (e.g., multiple errors in a same word line 365), read distress errors (e.g., multiple errors in a same sub-block 330), or both, using the parity pages. For example, by calculating the parity pages in such a fashion, the memory system may recover all pages of a sub-block group or all pages of a word line group (e.g., in the case of read distress errors or program disturb errors) in response to each parity element being calculated from a single page of each sub-block group and a single page from each word line group.

FIG. 4 shows an example of a parity configuration 400 that supports the parity scheme for read distress protection in a memory system in accordance with examples as disclosed herein. In some cases, aspects of the parity configuration 400 may implement or be implemented by aspects of FIGS. 1-3. For example, the parity configuration 400 may include a set of consecutive word lines 470 (e.g., such as the set of consecutive word lines 370), word lines 465 (e.g., word lines 465-a through 465-h, such as word lines 165, word lines 265, word lines 365), one or more pages of data (e.g., such as the pages 215) associated with one or more RAIN stripes, one or more SGSs 415 (e.g., SGSs 415-a through 415-h, such as SGSs 315), and one or more SGDs 410 (e.g., SGDs 410-a through 410-p, such as SGDs 310).

In the example of FIG. 4, there may be some quantity of RAIN stripes 0-M, where M may be 47 or some other quantity. In some cases, the one or more word lines 465 may each include one or more of the pages of data (e.g., a row of pages) over one or more planes of one or more memory dies. For example, a word line 465-a may include pages from a first row of a plane 450-a of a first memory die through pages from a first row of a plane 450-N of a second memory die (e.g., where the first and second memory die may be a same or different memory dies). The one or more pages 215 may store data, labeled as data 0 (D0) through data 47 (D47) in FIG. 4, or some other quantity of data. In some aspects, the parity configuration 400 may illustrate parity generation techniques for the parity scheme that provides protection against program disturb errors and read distress errors.

The parity scheme described herein may also be referred to as a RAIN scheme. For example, the set of consecutive word lines 470 may include one or more RAIN stripes, which may be groups of pages (e.g., RAIN stripe elements, 16 kilobyte (KB) data pages), where each page in a given RAIN stripe may correspond to a same parity page stored by the memory system. That is, the data stored in the pages of each RAIN stripe may be protected by one corresponding parity page. Stated differently, the memory system may combine each page of data of a RAIN stripe to generate parity information for the RAIN stripe. For example, data pages of the parity configuration 400 may be labeled D0-DM for M RAIN stripes (e.g., where M is any non-zero positive integer), such that each D0 page may correspond to a RAIN stripe 0, each D1 page may correspond to a RAIN stripe 1, and so on. Additionally, parity pages (e.g., 16 KB parity pages or some other size) of the parity configuration 400 may be labeled P0-PM for the M RAIN stripes, such that a P0 parity page may correspond to RAIN stripe 0, a P1 parity page may correspond to RAIN stripe 1, and so on. Each RAIN stripe may include as many pages (e.g., elements) as there are sub-block groups 430 or word line groups 425 in the set of consecutive word lines 470. For example, if the set of consecutive word lines 470 includes eight sub-block groups 430 (e.g., corresponding to SGSs 415-a through 415-h), each RAIN stripe may include eight pages, and thus the set of consecutive word lines 470 may include eight D0s, eight D1s, and so on.

In some cases, the parity scheme described herein may be associated with lower latency corresponding to fewer pages per RAIN stripe (e.g., a reduced quantity of RAIN stripe elements). For example, other parity schemes may include, in each RAIN stripe, one data page for each word line of each plane 450. However, depending on a quantity of word lines in the one or more planes 450, each RAIN stripe may include a relatively large quantity of data pages, in such schemes. The techniques described herein may calculate a word line group of parity pages per set of consecutive word lines 470, where each RAIN stripe may include as many data pages as a quantity of word line groups 425 (e.g., or sub-block groups 430) within the set of consecutive word lines, thereby reducing latency and overhead, among other examples.

The parity configuration 400 may include one or more planes 450 of one or more memory dies (not shown) that include the plurality of pages. For example, the parity configuration 400 may include any quantity of planes 450, including planes 450-a through 450-N. Each word line 465 may include the pages along one row of each plane 450. For example, word line 465-a may include the pages of the first row of plane 450-a through the plane 450-N, and each word line 465 may similarly include pages in corresponding rows of each plane 450. The word lines 465 may be organized into word line groups 425, which may include one or more adjacent word lines (e.g., two adjacent word lines, for example). The parity configuration 400 may depict a single set of consecutive word lines 470 (e.g., such as the set of consecutive word lines 370), but the techniques described herein may be applied to any quantity of sets of consecutive word lines 470, each of which may include any quantity of word lines 465, word line groups 425, pages, RAIN stripes, sub-block groups 430, or any other feature of the parity configuration 400.

In some aspects, the parity configuration 400 may illustrate an example of a TLC memory system, where each page of the parity configuration 400 may be one of a lower page (LP), an upper page (UP), or an extra page (XP). The techniques described herein may also apply to other memory systems, including SLC memory systems, MLC memory systems, QLC memory systems, any other level cell memory systems, or any combination thereof.

In the example of FIG. 4, each plane 450 may include one or more SGSs 415 (e.g., four SGSs 415, segmented SGSs such as described herein with respect to FIG. 3), and each SGS 415 may correspond to one or more SGDs 410 (e.g., two SGDs 410), where each SGD 410 may correspond to a sub-block of pages (e.g., a column of pages, such as the sub-blocks 330). It is to be understood that these examples are not limiting, and there may be any quantity of SGSs 415 per plane and SGDs 410 per SGS 415. Each sub-block may include a virtual sub-block of LPs, a virtual sub-block of UPs, and a virtual sub-block of XPs (e.g., a virtual sub-block for each page of the given memory cell, such as three page types for TLC, or other page types for other types of memory). In some examples, the parity configuration 400 may include one or more sub-block groups 430, where each sub-block group 430 may include one or more sub-blocks (e.g., or one or more virtual sub-blocks). In some cases, pages of a sub-block may be stacked in a column (e.g., vertically with respect to a substrate) and coupled in series between an SGS 315 (e.g., a shared source selector) and an SGD 310 (e.g., a respective drain selector), and each page of the column may be coupled with a respective word line 465 of the set of consecutive word lines 470. In some examples, a set of sub-blocks (e.g., or virtual sub-blocks) corresponding to (e.g., coupled with) a same SGS 415 (e.g., a shared source selector) may be a sub-block group 430 (e.g., each SGS 415 may correspond to a sub-block group, such as SGS 415-c corresponding to the sub-block group 430).

The parity scheme described herein may leverage the segmentation of the SGSs 415 to improve RAIN protection operations. For example, each word line group 425 and each sub-block group 430 may include one page from each RAIN stripe of the set of consecutive word lines 470. For example, the set of consecutive word lines 470 may include RAIN stripes 0-M (e.g., 47, for example), and thus each sub-block group and each word line group may include M+1 pages (e.g., 48 pages, each from a different RAIN stripe). Additionally, each page from each RAIN stripe may be stored in a different location in each sub-block group 430 and each word line group 425 of the set of consecutive word lines 470 within a plane 450. For example, if the sub-block group 430 from the plane 450-a stores a D12 page (e.g., a first page from a RAIN stripe 12) in an upper-left-most entry, no other sub-block group 430 within the set of consecutive word lines 470 in the plane 450-a may store another D12 page (e.g., a second page from the RAIN stripe 12) in the upper-left-most entry. Similarly, if the word line group 425 of plane 450-a stores a D29 page (e.g., a first page from a RAIN stripe 29) in an upper-right-most entry, no other word line group 425 of plane 450-a may store a D29 page (e.g., a second page from the RAIN stripe 29) in the upper-right-most entry. The assignments between pages and RAIN strips may be applied in such a way that these rules are true across the memory system. In some examples, the RAIN stripe configuration may be programmed on the memory system, or a memory system controller may determine the RAIN stripe configuration, or some other technique.

The memory system may calculate one or more parity pages (e.g., parity information included in one or more parity elements, P0-PM) for data before, during, or after writing the data to one or more data pages of the set of consecutive word lines 470. The memory system may calculate each parity page according to the data pages of a respective RAIN stripe of the set of consecutive word lines 470. For example, to calculate a parity page (e.g., parity information corresponding to a RAIN stripe of the set of consecutive word lines 470), the memory system may combine one page from each word line group 425 and each sub-block group 430 of the set of consecutive word lines 470, where the one page belongs to the RAIN stripe. That is, to generate each parity page P0-PM, the memory system may combine a respective set of data pages of the set of consecutive word lines 470, where each respective set of data pages may include one data page per sub-block group 430 and per word line group 425. A set of pages associated with the RAIN stripe 0, for example, may include all pages labeled D0 in FIG. 4. As illustrated, there may be a single D0 in each sub-block group 430 and a single D0 in each word line group 425 (e.g., any two consecutive word lines 465). The word line groups 425 and sub-block groups 430 of the set of consecutive word lines 470 may overlap within a plane 450, and thus each respective set of pages may include a quantity of pages (e.g., M) equal to a quantity of sub-block groups 430 and equal to a quantity of word line groups 425 within the set of consecutive word lines 470. In some cases, combining a set of pages may include performing an XOR operation on the set of pages.

The memory system may store the one or more calculated parity pages (e.g., P0-PM, parity elements) in a parity word line group 435 of the set of consecutive word lines 470, where the memory system may use the parity pages for recovery of data stored in the one or more word line groups 425 (e.g., remaining word line groups) of the set of consecutive word lines 470. For example, the memory system may calculate the parity pages (e.g., parity information) while writing data pages to the set of consecutive word lines 470, and thus the memory system may store the calculated parity pages in a temporally last written word line group (e.g., the parity word line group 435) of the set of consecutive word lines 470. In some cases, the temporally last written word line may be in the plane 450-N, or any other plane from plane 450-a to plane 450-N. For example, after writing a set quantity of data (e.g., 48,384 KB of data or some other quantity), the memory system may flush parity pages (e.g., 48 parities, 768 KB of parity information) to the parity word line group 435 to enable program and read disturb protection. In some cases, the quantity M of parity pages for the set of consecutive word lines 470 may be associated with the quantity of SGDs 410, SGSs 415 per SGD 410, a write mode used on the data pages, and a quantity of word lines 465 per word line group 425. For example, in a memory system that includes four SGSs per plane, two SGDs per SGS, and three pages per SGD (e.g., TLC write mode), and two word lines per word line group, each set of consecutive word lines may include 48 parity pages (e.g., 4 SGSs×2 SGDs×3 pages×2 word lines=48 parity pages)).

In some examples, the one or more planes 450 may include one or more sets of consecutive word lines 470. In such examples, the memory system may calculate parity pages for each RAIN stripe of each respective set of consecutive word lines 470, and may store the parity pages for a respective set of consecutive word lines 470 within a respective parity word line group 435 of the respective set of consecutive word lines 470.

As an example, a memory system may receive a command to write data, and the memory system may write the data to one or more pages in one or more word lines 465, where the one or more pages may be of one or more RAIN stripes of the set of consecutive word lines 470, such as RAIN stripes 30 and 31. That is, the memory system may write the data to a D30 page and a D31 page of the one or more word lines 465, where each word line group 425 and each sub-block group 430 of the set of consecutive word lines 470 may include one D30 page and one D31 page. Before, during, or after writing the data to the pages, the memory system may combine (e.g., XOR) the data stored in the D30 pages of the set of consecutive word lines 470 to generate a parity page (e.g., parity information) for the RAIN stripe 30 (e.g., P30). After generating the parity page for RAIN stripe 30 using the newly written data, the memory system may write the parity page to the P30 parity page in the parity word line group 435. The memory system may repeat such combining and storing for each other RAIN stripe with newly written data (e.g., D31) until parity pages (e.g., P31) are generated for all of the newly written data. In some examples, not all of the data may be newly written, and the newly written data may be combined with previously written data to generate the corresponding parity information.

Such a parity scheme may provide for recovery of data stored in the set of consecutive word lines 470 after one or more program disturb errors (e.g., in a same word line group 425) and read distress errors (e.g., in a same sub-block group 430). For example, the memory system may recover data for an errored page of a RAIN stripe by combining each un-errored page in the RAIN stripe (e.g., all the pages in the RAIN stripe but one) with the parity page for the RAIN stripe. Thus, in the case of a program disturb error (e.g., multiple pages within a word line 465 incur errors), the memory system may use corresponding parity pages to correct the errors (e.g., since each word line group 425 has a single page from each RAIN stripe). In the case of a read distress error (e.g., multiple pages in a same sub-block or virtual sub-block incur errors), the memory system may use corresponding parity pages to correct the errors. The memory system may use such a parity scheme to correct program disturb errors and read distress errors simultaneously, such as if the program disturb errors and the read distress errors do not cause more than some threshold quantity of pages (e.g., two pages, or some other quantity at which RAIN recovery may fail) from a same RAIN stripe to incur an error. Such a parity scheme may be used to correct errors corresponding to one or more other causes.

As an example, one or more data pages of the sub-block group 430 (e.g., a portion of data stored in the sub-block group 430) may incur errors. In some cases, the one or more data pages may be associated with two different word lines 465. For example, a D19 page, a D1 page, and a D25 page from the sub-block group 430 may be coupled with the SGS 415-c, and such pages may be errored pages due to read distress from reading pages of another sub-lock (e.g., or virtual sub-block) that is also coupled with the SGS 415-c. To obtain the correct data of D19 in sub-block group 430 (e.g., to correct D19), the memory system may combine (e.g., XOR) a P19 parity page from the parity word line group 435 with the D19 pages from every other sub-block group 430 within the set of consecutive word lines 470 and perform one or more other RAIN recovery operations. The memory system may then write the corrected (e.g., accurate, un-errored) data back to the D19 page of sub-block 330, and repeat the process to correct D1 and D25. The memory system may follow a similar process to correct multiple errored pages within a word line group 425 using a corresponding parity page and a corresponding data page from every other word line group 425.

Accordingly, a memory system implementing these techniques may be associated with increased data protection and security at least because the memory system may correct errors that occur after a read operation causes stress in a stacked memory architecture. Additionally, the memory system may be associated with less latency due to RAIN recovery time. For example, RAIN recovery time may be a time used to recover errored data, and may be decreased to protect fewer data pages per parity pages (e.g., including fewer data pages in each RAIN stripe), thereby reducing a time for recovering errored data. Additionally, or alternatively, the RAIN recovery time may be decreased by implementing a parity scheme that protects against more errors (e.g., like read distress errors).

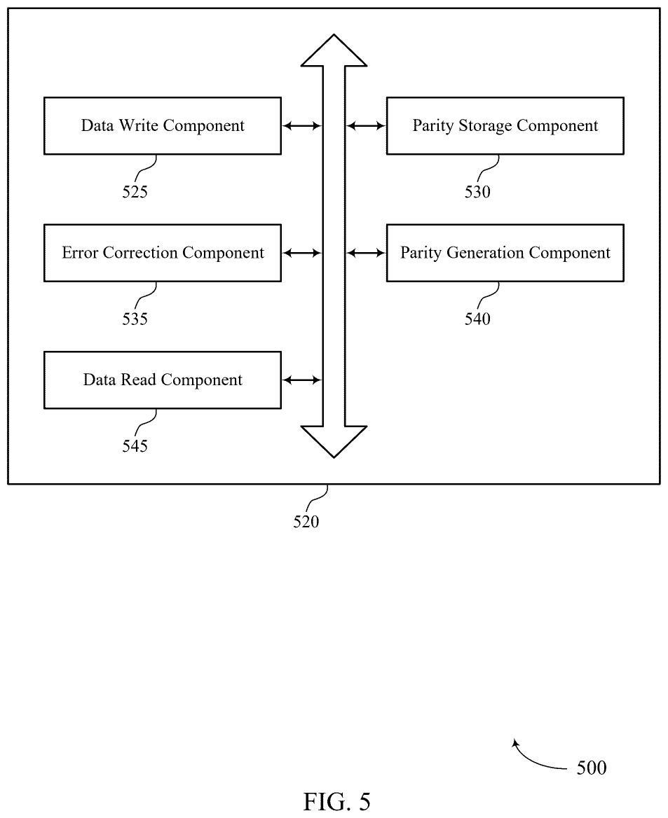

FIG. 5 shows a block diagram 500 of a memory system 520 that supports the parity scheme for read distress protection in a memory system in accordance with examples as disclosed herein. The memory system 520 may be an example of aspects of a memory system as described with reference to FIGS. 1 through 4. The memory system 520, or various components thereof, may be an example of means for performing various aspects of parity scheme for read distress protection in a memory system as described herein. For example, the memory system 520 may include a data write component 525, a parity storage component 530, an error correction component 535, a parity generation component 540, a data read component 545, or any combination thereof. Each of these components, or components of subcomponents thereof (e.g., one or more processors, one or more memories), may communicate, directly or indirectly, with one another (e.g., via one or more buses).

The data write component 525 may be configured as or otherwise support a means for writing data to a plurality of pages in a set of consecutive word lines within one or more planes of a memory system, where each page of the plurality of pages is included in a respective word line group of a plurality of word line groups and a respective sub-block group of a plurality of sub-block groups of the memory system. The parity storage component 530 may be configured as or otherwise support a means for storing, in a first word line group of the plurality of word line groups, parity information for recovery of the data stored in one or more remaining word line groups of the plurality of word line groups, the parity information including a plurality of parity elements each generated in accordance with a respective set of pages of the plurality of pages, the respective set of pages including a single page from each word line group of the plurality of word line groups and a single page from each sub-block group of the plurality of sub-block groups. The error correction component 535 may be configured as or otherwise support a means for correcting, in accordance with the parity information, errors in a portion of the data associated with a first sub-block group of the plurality of sub-block groups and at least two word lines.

In some examples, each sub-block group of the plurality of sub-block groups includes one or more first subsets of pages coupled with a shared source selector, each first subset of the one or more first subsets of pages included in a respective word line of the set of consecutive word lines. In some examples, each sub-block group of the plurality of sub-block groups includes one or more sub-blocks. In some examples, each sub-block of the one or more sub-blocks includes a respective first subset of pages of the one or more first subsets of pages, the respective first subset of pages coupled with a respective drain selector and the shared source selector.

In some examples, the data read component 545 may be configured as or otherwise support a means for reading, in accordance with activation of the shared source selector after storing the parity information and before correcting the errors, a second portion of the data from one or more pages of a first sub-block within the first sub-block group, where the portion of the data that includes the errors is stored within one or more sub-blocks within the first sub-block group, the errors in the portion of the data generated in response to the activation of the shared source selector.

In some examples, the respective first subset of pages of each sub-block of the one or more sub-blocks includes pages stacked in a column and coupled in series between the shared source selector and the respective drain selector. In some examples, each page of the column of pages in a sub-block is coupled with a respective word line of the set of consecutive word lines.

In some examples, to support correcting the errors in the portion of the data, the error correction component 535 may be configured as or otherwise support a means for performing one or more operations to recover the portion of the data, the one or more operations performed in accordance with the parity information and one or more pages within one or more second sub-block groups of the plurality of sub-block groups.

In some examples, the data write component 525 may be configured as or otherwise support a means for writing second data to one or more pages of a second word line group including two adjacent word lines of the set of consecutive word lines, where one or more second errors in a third word line group that is next to the second word line group are generated in response to writing the second data. In some examples, the error correction component 535 may be configured as or otherwise support a means for correcting, in accordance with the parity information, the one or more second errors in the third word line group.

In some examples, to support writing the data to the plurality of pages, the data write component 525 may be configured as or otherwise support a means for writing the data to one or more second word line groups of the plurality of word line groups. In some examples, to support writing the data to the plurality of pages, the data write component 525 may be configured as or otherwise support a means for generating the parity information in accordance with the data. In some examples, to support writing the data to the plurality of pages, the data write component 525 may be configured as or otherwise support a means for storing the parity information to the first word line group after writing the data to the one or more second word line groups, the first word line group including a last word line group of a last plane of the one or more planes of the memory system.

In some examples, the parity generation component 540 may be configured as or otherwise support a means for generating the plurality of parity elements in accordance with the data written to the plurality of pages, where each parity element of the plurality of parity elements is generated in accordance with an exclusive OR combination of each page of the respective set of pages associated with the respective parity element.

In some examples, the data write component 525 may be configured as or otherwise support a means for writing second data to a second plurality of pages in a second set of consecutive word lines within the one or more planes of the memory system, where each page of the second plurality of pages is included in a respective word line group of a second plurality of word line groups and a respective sub-block group of a second plurality of sub-block groups of the memory system. In some examples, the parity storage component 530 may be configured as or otherwise support a means for storing, in a second word line group of the second plurality of word line groups, second parity information for recovery of the data stored in one or more second remaining word line groups of the second plurality of word line groups in the second set of consecutive word lines, the second parity information including a second plurality of parity elements, where each parity element of the second plurality of parity elements is generated in accordance with a respective second set of pages of the second plurality of pages, the respective second set of pages including a single page from each word line group of the second plurality of word line groups and a single page from each sub-block group of the second plurality of sub-block groups.

In some examples, each sub-block group of the plurality of sub-block groups includes a first quantity of pages. In some examples, each word line group of the plurality of word line groups includes the first quantity of pages. In some examples, a second quantity of parity elements included in the plurality of parity elements is equal to a third quantity of sub-block groups within the set of consecutive word lines, the second quantity of parity elements comprising a RAIN stripe of the memory system.

In some examples, the described functionality of the memory system 520, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 520, or various components thereof, may be implemented at least in part by instructions (e.g., stored in memory, non-transitory computer-readable medium) executable by such at least one processor.

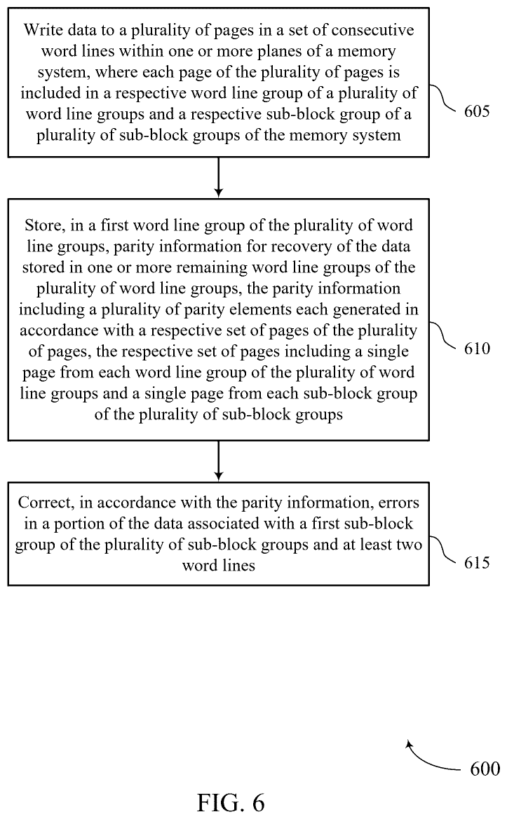

FIG. 6 shows a flowchart illustrating a method 600 that supports the parity scheme for read distress protection in a memory system in accordance with examples as disclosed herein. The operations of method 600 may be implemented by a memory system or its components as described herein. For example, the operations of method 600 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 605, the method may include writing data to a plurality of pages in a set of consecutive word lines within one or more planes of a memory system, where each page of the plurality of pages is included in a respective word line group of a plurality of word line groups and a respective sub-block group of a plurality of sub-block groups of the memory system. In some examples, aspects of the operations of 605 may be performed by a data write component 525 as described with reference to FIG. 5.

At 610, the method may include storing, in a first word line group of the plurality of word line groups, parity information for recovery of the data stored in one or more remaining word line groups of the plurality of word line groups, the parity information including a plurality of parity elements each generated in accordance with a respective set of pages of the plurality of pages, the respective set of pages including a single page from each word line group of the plurality of word line groups and a single page from each sub-block group of the plurality of sub-block groups. In some examples, aspects of the operations of 610 may be performed by a parity storage component 530 as described with reference to FIG. 5.

At 615, the method may include correcting, in accordance with the parity information, errors in a portion of the data associated with a first sub-block group of the plurality of sub-block groups and at least two word lines. In some examples, aspects of the operations of 615 may be performed by an error correction component 535 as described with reference to FIG. 5.

In some examples, an apparatus (e.g., a memory system) as described herein may perform a method or methods, such as the method 600. The apparatus (e.g., memory system) may include features, circuitry, logic, means, or instructions (e.g., a non-transitory computer-readable medium storing instructions (e.g., code comprising instruction) executable by processing circuitry), or any combination thereof for performing the following aspects of the present disclosure:

Aspect 1: A method, apparatus (e.g., memory system), or non-transitory computer-readable medium including operations, features, circuitry, logic, means, or instructions, or any combination thereof for writing data to a plurality of pages in a set of consecutive word lines within one or more planes of a memory system, where each page of the plurality of pages is included in a respective word line group of a plurality of word line groups and a respective sub-block group of a plurality of sub-block groups of the memory system; storing, in a first word line group of the plurality of word line groups, parity information for recovery of the data stored in one or more remaining word line groups of the plurality of word line groups, the parity information including a plurality of parity elements each generated in accordance with a respective set of pages of the plurality of pages, the respective set of pages including a single page from each word line group of the plurality of word line groups and a single page from each sub-block group of the plurality of sub-block groups; and correcting, in accordance with the parity information, errors in a portion of the data associated with a first sub-block group of the plurality of sub-block groups and at least two word lines.

Aspect 2: The method, apparatus, or non-transitory computer-readable medium of aspect 1, where each sub-block group of the plurality of sub-block groups includes one or more first subsets of pages coupled with a shared source selector, each first subset of the one or more first subsets of pages included in a respective word line of the set of consecutive word lines; each sub-block group of the plurality of sub-block groups includes one or more sub-blocks; and each sub-block of the one or more sub-blocks includes a respective first subset of pages of the one or more first subsets of pages, the respective first subset of pages coupled with a respective drain selector and the shared source selector.

Aspect 3: The method, apparatus, or non-transitory computer-readable medium of aspect 2, further including operations, features, circuitry, logic, means, or instructions, or any combination thereof for reading, in accordance with activation of the shared source selector after storing the parity information and before correcting the errors, a second portion of the data from one or more pages of a first sub-block within the first sub-block group, where the portion of the data that includes the errors is stored within one or more sub-blocks within the first sub-block group, the errors in the portion of the data generated in response to the activation of the shared source selector.

Aspect 4: The method, apparatus, or non-transitory computer-readable medium of any of aspects 2 through 3, where the respective first subset of pages of each sub-block of the one or more sub-blocks includes pages stacked in a column and coupled in series between the shared source selector and the respective drain selector and each page of the column of pages in a sub-block is coupled with a respective word line of the set of consecutive word lines.

Aspect 5: The method, apparatus, or non-transitory computer-readable medium of any of aspects 1 through 4, where correcting the errors in the portion of the data includes operations, features, circuitry, logic, means, or instructions, or any combination thereof for performing one or more operations to recover the portion of the data, the one or more operations performed in accordance with the parity information and one or more pages within one or more second sub-block groups of the plurality of sub-block groups.

Aspect 6: The method, apparatus, or non-transitory computer-readable medium of any of aspects 1 through 5, further including operations, features, circuitry, logic, means, or instructions, or any combination thereof for writing second data to one or more pages of a second word line group including two adjacent word lines of the set of consecutive word lines, where one or more second errors in a third word line group that is next to the second word line group are generated in response to writing the second data and correcting, in accordance with the parity information, the one or more second errors in the third word line group.

Aspect 7: The method, apparatus, or non-transitory computer-readable medium of any of aspects 1 through 6, where writing the data to the plurality of pages includes operations, features, circuitry, logic, means, or instructions, or any combination thereof for writing the data to one or more second word line groups of the plurality of word line groups; generating the parity information in accordance with the data; and storing the parity information to the first word line group after writing the data to the one or more second word line groups, the first word line group including a last word line group of a last plane of the one or more planes of the memory system.

Aspect 8: The method, apparatus, or non-transitory computer-readable medium of any of aspects 1 through 7, further including operations, features, circuitry, logic, means, or instructions, or any combination thereof for generating the plurality of parity elements in accordance with the data written to the plurality of pages, where each parity element of the plurality of parity elements is generated in accordance with an exclusive OR combination of each page of the respective set of pages associated with the respective parity element.

Aspect 9: The method, apparatus, or non-transitory computer-readable medium of any of aspects 1 through 8, further including operations, features, circuitry, logic, means, or instructions, or any combination thereof for writing second data to a second plurality of pages in a second set of consecutive word lines within the one or more planes of the memory system, where each page of the second plurality of pages is included in a respective word line group of a second plurality of word line groups and a respective sub-block group of a second plurality of sub-block groups of the memory system and storing, in a second word line group of the second plurality of word line groups, second parity information for recovery of the data stored in one or more second remaining word line groups of the second plurality of word line groups in the second set of consecutive word lines, the second parity information including a second plurality of parity elements, where each parity element of the second plurality of parity elements is generated in accordance with a respective second set of pages of the second plurality of pages, the respective second set of pages including a single page from each word line group of the second plurality of word line groups and a single page from each sub-block group of the second plurality of sub-block groups.

Aspect 10: The method, apparatus, or non-transitory computer-readable medium of any of aspects 1 through 9, where each sub-block group of the plurality of sub-block groups includes a first quantity of pages; each word line group of the plurality of word line groups includes the first quantity of pages; and a second quantity of parity elements included in the plurality of parity elements is equal to a third quantity of sub-block groups within the set of consecutive word lines, the second quantity of parity elements comprising a RAIN stripe of the memory system.

It should be noted that the described methods include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit according to the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
write data to a plurality of pages in a set of consecutive word lines within one or more planes of a memory system, wherein each page of the plurality of pages is included in a respective word line group of a plurality of word line groups and a respective sub-block group of a plurality of sub-block groups of the memory system;
store, in a first word line group of the plurality of word line groups, parity information for recovery of the data stored in one or more remaining word line groups of the plurality of word line groups, the parity information comprising a plurality of parity elements each generated in accordance with a respective set of pages of the plurality of pages, the respective set of pages comprising a single page from each word line group of the plurality of word line groups and a single page from each sub-block group of the plurality of sub-block groups; and
correct, in accordance with the parity information, errors in a portion of the data associated with a first sub-block group of the plurality of sub-block groups and at least two word lines.

2. The memory system of claim 1, wherein each sub-block group of the plurality of sub-block groups comprises one or more first subsets of pages coupled with a shared source selector, each first subset of the one or more first subsets of pages included in a respective word line of the set of consecutive word lines, wherein each sub-block group of the plurality of sub-block groups comprises one or more sub-blocks, and wherein each sub-block of the one or more sub-blocks comprises a respective first subset of pages of the one or more first subsets of pages, the respective first subset of pages coupled with a respective drain selector and the shared source selector.

3. The memory system of claim 2, wherein the processing circuitry is further configured to cause the memory system to:
read, in accordance with activation of the shared source selector after storing the parity information and before correcting the errors, a second portion of the data from one or more pages of a first sub-block within the first sub-block group, wherein the portion of the data that comprises the errors is stored within one or more sub-blocks within the first sub-block group, the errors in the portion of the data generated in response to the activation of the shared source selector.

4. The memory system of claim 2, wherein the respective first subset of pages of each sub-block of the one or more sub-blocks comprises pages stacked in a column and coupled in series between the shared source selector and the respective drain selector, and wherein each page of the column of pages in a sub-block is coupled with a respective word line of the set of consecutive word lines.

5. The memory system of claim 1, wherein, to correct the errors in the portion of the data, the processing circuitry is configured to cause the memory system to:
perform one or more operations to recover the portion of the data, the one or more operations performed in accordance with the parity information and one or more pages within one or more second sub-block groups of the plurality of sub-block groups.

6. The memory system of claim 1, wherein the processing circuitry is further configured to cause the memory system to:
write second data to one or more pages of a second word line group comprising two adjacent word lines of the set of consecutive word lines, wherein one or more second errors in a third word line group that is next to the second word line group are generated in response to writing the second data; and
correct, in accordance with the parity information, the one or more second errors in the third word line group.

7. The memory system of claim 1, wherein, to write the data to the plurality of pages, the processing circuitry is configured to cause the memory system to:
write the data to one or more second word line groups of the plurality of word line groups;
generate the parity information in accordance with the data; and
store the parity information to the first word line group after writing the data to the one or more second word line groups, the first word line group comprising a last word line group of a last plane of the one or more planes of the memory system.

8. The memory system of claim 1, wherein the processing circuitry is further configured to cause the memory system to:
generate the plurality of parity elements in accordance with the data written to the plurality of pages, wherein each parity element of the plurality of parity elements is generated in accordance with an exclusive OR combination of each page of the respective set of pages associated with the respective parity element.

9. The memory system of claim 1, wherein the processing circuitry is further configured to cause the memory system to:
write second data to a second plurality of pages in a second set of consecutive word lines within the one or more planes of the memory system, wherein each page of the second plurality of pages is included in a respective word line group of a second plurality of word line groups and a respective sub-block group of a second plurality of sub-block groups of the memory system; and
store, in a second word line group of the second plurality of word line groups, second parity information for recovery of the data stored in one or more second remaining word line groups of the second plurality of word line groups in the second set of consecutive word lines, the second parity information comprising a second plurality of parity elements, wherein each parity element of the second plurality of parity elements is generated in accordance with a respective second set of pages of the second plurality of pages, the respective second set of pages comprising a single page from each word line group of the second plurality of word line groups and a single page from each sub-block group of the second plurality of sub-block groups.

10. The memory system of claim 1, wherein each sub-block group of the plurality of sub-block groups comprises a first quantity of pages, wherein each word line group of the plurality of word line groups comprises the first quantity of pages, and wherein a second quantity of parity elements included in the plurality of parity elements is equal to a third quantity of sub-block groups within the set of consecutive word lines, the second quantity of parity elements comprising a redundant array of independent NOT-AND (NAND) stripe of the memory system.

11. A non-transitory computer-readable medium storing code comprising instructions which, when executed by processing circuitry of a memory system, cause the memory system to:
write data to a plurality of pages in a set of consecutive word lines within one or more planes of a memory system, wherein each page of the plurality of pages is included in a respective word line group of a plurality of word line groups and a respective sub-block group of a plurality of sub-block groups of the memory system;
store, in a first word line group of the plurality of word line groups, parity information for recovery of the data stored in one or more remaining word line groups of the plurality of word line groups, the parity information comprising a plurality of parity elements each generated in accordance with a respective set of pages of the plurality of pages, the respective set of pages comprising a single page from each word line group of the plurality of word line groups and a single page from each sub-block group of the plurality of sub-block groups; and
correct, in accordance with the parity information, errors in a portion of the data associated with a first sub-block group of the plurality of sub-block groups and at least two word lines.

12. The non-transitory computer-readable medium of claim 11, wherein each sub-block group of the plurality of sub-block groups comprises one or more first subsets of pages coupled with a shared source selector, each first subset of the one or more first subsets of pages included in a respective word line of the set of consecutive word lines, wherein each sub-block group of the plurality of sub-block groups comprises one or more sub-blocks, and wherein each sub-block of the one or more sub-blocks comprises a respective first subset of pages of the one or more first subsets of pages, the respective first subset of pages coupled with a respective drain selector and the shared source selector.

13. The non-transitory computer-readable medium of claim 12, wherein the instructions, when executed by processing circuitry of a memory system, further cause the memory system to:
read, in accordance with activation of the shared source selector after storing the parity information and before correcting the errors, a second portion of the data from one or more pages of a first sub-block within the first sub-block group, wherein the portion of the data that comprises the errors is stored within one or more sub-blocks within the first sub-block group, the errors in the portion of the data generated in response to the activation of the shared source selector.

14. The non-transitory computer-readable medium of claim 12, wherein the respective first subset of pages of each sub-block of the one or more sub-blocks comprises pages stacked in a column and coupled in series between the shared source selector and the respective drain selector, and wherein each page of the column of pages in a sub-block is coupled with a respective word line of the set of consecutive word lines.

15. The non-transitory computer-readable medium of claim 11, wherein the instructions to correct the errors in the portion of the data, when executed by processing circuitry of a memory system, cause the memory system to:
perform one or more operations to recover the portion of the data, the one or more operations performed in accordance with the parity information and one or more pages within one or more second sub-block groups of the plurality of sub-block groups.

16. The non-transitory computer-readable medium of claim 11, wherein the instructions, when executed by processing circuitry of a memory system, further cause the memory system to:
write second data to one or more pages of a second word line group comprising two adjacent word lines of the set of consecutive word lines, wherein one or more second errors in a third word line group that is next to the second word line group are generated in response to writing the second data; and
correct, in accordance with the parity information, the one or more second errors in the third word line group.

17. The non-transitory computer-readable medium of claim 11, wherein the instructions to write the data to the plurality of pages, when executed by processing circuitry of a memory system, cause the memory system to:
write the data to one or more second word line groups of the plurality of word line groups;
generate the parity information in accordance with the data; and
store the parity information to the first word line group after writing the data to the one or more second word line groups, the first word line group comprising a last word line group of a last plane of the one or more planes of the memory system.

18. The non-transitory computer-readable medium of claim 11, wherein the instructions, when executed by processing circuitry of a memory system, further cause the memory system to:
generate the plurality of parity elements in accordance with the data written to the plurality of pages, wherein each parity element of the plurality of parity elements is generated in accordance with an exclusive OR combination of each page of the respective set of pages associated with the respective parity element.

19. The non-transitory computer-readable medium of claim 11, wherein the instructions, when executed by processing circuitry of a memory system, further cause the memory system to:
write second data to a second plurality of pages in a second set of consecutive word lines within the one or more planes of the memory system, wherein each page of the second plurality of pages is included in a respective word line group of a second plurality of word line groups and a respective sub-block group of a second plurality of sub-block groups of the memory system; and
store, in a second word line group of the second plurality of word line groups, second parity information for recovery of the data stored in one or more second remaining word line groups of the second plurality of word line groups in the second set of consecutive word lines, the second parity information comprising a second plurality of parity elements, wherein each parity element of the second plurality of parity elements is generated in accordance with a respective second set of pages of the second plurality of pages, the respective second set of pages comprising a single page from each word line group of the second plurality of word line groups and a single page from each sub-block group of the second plurality of sub-block groups.

20. The non-transitory computer-readable medium of claim 11, wherein each sub-block group of the plurality of sub-block groups comprises a first quantity of pages, wherein each word line group of the plurality of word line groups comprises the first quantity of pages, and wherein a second quantity of parity elements included in the plurality of parity elements is equal to a third quantity of sub-block groups within the set of consecutive word lines, the second quantity of parity elements comprising a RAIN stripe of the memory system.

21. A method, comprising:
writing data to a plurality of pages in a set of consecutive word lines within one or more planes of a memory system, wherein each page of the plurality of pages is included in a respective word line group of a plurality of word line groups and a respective sub-block group of a plurality of sub-block groups of the memory system;
storing, in a first word line group of the plurality of word line groups, parity information for recovery of the data stored in one or more remaining word line groups of the plurality of word line groups, the parity information comprising a plurality of parity elements each generated in accordance with a respective set of pages of the plurality of pages, the respective set of pages comprising a single page from each word line group of the plurality of word line groups and a single page from each sub-block group of the plurality of sub-block groups; and
correcting, in accordance with the parity information, errors in a portion of the data associated with a first sub-block group of the plurality of sub-block groups and at least two word lines.

22. The method of claim 21, wherein each sub-block group of the plurality of sub-block groups comprises one or more first subsets of pages coupled with a shared source selector, each first subset of the one or more first subsets of pages included in a respective word line of the set of consecutive word lines, wherein each sub-block group of the plurality of sub-block groups comprises one or more sub-blocks, and wherein each sub-block of the one or more sub-blocks comprises a respective first subset of pages of the one or more first subsets of pages, the respective first subset of pages coupled with a respective drain selector and the shared source selector.
